(19) United States
(12) Patent Application Publication
(10) Pub. No.: US 2011/0094587 A1
(43) Pub. Date: Apr. 28, 2011

(54) METHOD FOR CONTROLLING SELF-ASSEMBLED SRUCTURE OF POLY(3-HEXYLTHIOPHENE)-BASED BLOCK COPOLYMER

(75) Inventors: Kyung Youl BAEK, Seoul (KR); Hoichang Yang, Incheon (KR); Seung Sang Hwang, Seoul (KR); Yeon Hee Choi, Chuncheon-si (KR); Yun-Jae Lee, Ansan-si (KR); Dong Yeop Oh, Busan (KR); Han Sup Lee, Incheon (KR)

(73) Assignee: Korea Institute of Science & Technology, Seoul (KR)

(21) Appl. No.: 12/707,392

(22) Filed: Feb. 17, 2010

(30) Foreign Application Priority Data
Oct. 28, 2009 (KR) 10-2009-0102960

(51) Int. Cl. H01L 31/0256; H01L 51/40; H01L 51/30

(52) U.S. Cl. 136/263; 438/99; 257/40; 257/E51.029; 977/762

(57) ABSTRACT

Provided is a method for controlling a self-assembled structure of a poly(3-hexylthiophene)-based block copolymer, including: providing a polymer composition containing a block copolymer having a π-conjugated poly(3-hexylthiophene) polymer and a non-conjugated polymer introduced thereto, and a solvent; and coating the polymer composition onto a substrate.

According to the method disclosed herein, it is possible to control a self-assembled structure of a poly(3-hexylthiophene)-based block copolymer merely by a relatively simple process including coating the poly(3-hexylthiophene)-based block copolymer onto a substrate with a selected solvent. In this manner, it is possible to control the alignment of conductive domains in the block copolymer so that it is suitable for various organic electronic devices. In addition, the self-assembled polymer structure having various self-assembled structures controlled selectively by the method may be applied to organic electronic devices for designing and developing high-quality devices.

### CROSS-REFERENCE TO RELATED APPLICATIONS

This application claims priority to Korean Patent Application No. 10-2009-0102960, filed on Oct. 28, 2009, and which application is incorporated herein by reference. A claim of priority to all, to the extent appropriate is made.

### BACKGROUND

1. Field of the Invention

This disclosure relates to a method for controlling a self-assembled structure of a poly(3-hexylthiophene)-based block copolymer, a self-assembled polymer structure having a controlled self-assembled structure, and an organic electronic device including a self-assembled polymer structure.

2. Description of the Related Art

Recently, organic photovoltaics have been intensively studied as a so-called green growth policy has been developed. Modern information-display device industries focus on the easy portability, flexibility, weight reduction, enlargement and display rate acceleration in various image media. More recently, as a part of ways for satisfying such requirements, active studies have been conducted for developing organic electronic devices provided with high cost efficiency, excellent durability and flexibility and high quality using organic semiconductor polymers capable of performing a solution filming process instead of general inorganic semiconductors.

Like general inorganic semiconductors, conductive organic semiconductor materials may be classified into p-type semiconductors, in which holes serve as charge carriers, and n-type semiconductors, in which electrons serve as charge carriers. Most organic semiconductor materials have a conjugation structure containing periodically alternating σ and π bonds so that electrons are not limited to a local zone in a molecule but are widely distributed therein.

A typical example of p-type organic semiconductor materials, poly(3-hexylthiophene) (P3HT) shows a strong π-π intermolecular attraction force, and thus provides a highly crystalline nanofiber network when formed into a thin film on a substrate, and realizes excellent device quality.

However, when observed from a macroscopic view, the poly(3-hexylthiophene) crystal structure shows a problem like other crystalline polymers. In other words, due to the spherulitic growth from base nuclei formed at the initial phase of the crystallization of poly(3-hexylthiophene), the efficiency of charge transport between nanofibers is decreased by an excessively large number of nano/micro crystal boundaries. In addition, during a solution process, such as an ink-jet process, for developing large-area devices, spraying from a nozzle is not easy because of low solubility to a solvent.

Therefore, there is an imminent need for improving the morphology, including the crystal structure, of poly(3-hexylthiophene) as a π-conjugated crystalline polymer in order to develop high-quality organic electronic devices.

### SUMMARY

Disclosed herein is a method for controlling a self-assembled structure of a poly(3-hexylthiophene)-based block copolymer merely by a simple process including coating a polymer composition, containing a poly(3-hexylthiophene)-based block copolymer having a non-conjugated polymer block introduced thereto and a solvent, onto a substrate. Disclosed herein too is a self-assembled polymer structure having various self-assembled structures controlled selectively according to the above method, and use thereof in organic electronic devices for designing and developing high-quality devices.

In one aspect, there is provided a method for controlling a self-assembled structure of a poly(3-hexylthiophene)-based block copolymer, including: providing a polymer composition containing a block copolymer having a π-conjugated poly(3-hexylthiophene) polymer and a non-conjugated polymer introduced thereto, and a solvent; and coating the polymer composition onto a substrate.

In another aspect, there is provided a self-assembled polymer structure including a π-conjugated poly(3-hexylthiophene)-based block copolymer and having a self-assembled structure controlled by coating a polymer composition, containing a block copolymer having a non-conjugated polymer introduced to the poly(3-hexylthiophene) polymer and a solvent, onto a substrate.

In still another aspect, there is provided an organic electronic device including the self-assembled polymer structure.

According to the method disclosed herein, it is possible to control a self-assembled structure of a poly(3-hexylthiophene)-based block copolymer so that it is suitable for providing various organic electronic devices with high quality, merely by a relatively simple process including coating the poly(3-hexylthiophene)-based block copolymer onto a substrate with a selected solvent to a certain thickness. It is also possible to apply the self-assembled polymer structures having various self-assembled structures controlled selectively by the method to general organic electronic devices for designing and developing high-quality devices.

### BRIEF DESCRIPTION OF THE DRAWINGS

The above and other aspects, features and advantages of the disclosed exemplary embodiments will be more apparent from the following detailed description taken in conjunction with the accompanying drawings in which:

FIG. 1 is a photographic view illustrating the atomic force microscope (AFM) images (a to d) of a self-assembled polymer structure having different alignments depending on the coating thickness on a substrate according to one embodiment of the method disclosed herein;

FIG. 2 is grazing-incidence X-ray diffractometry (GIXD) patterns (a) illustrating self-assembled polymer structure having different alignments depending on the coating thickness and materials used on a substrate and a schematic view (b) illustrating a process of forming a self-assembled P3HT-b-PMMA block copolymer structure having different alignments depending on the thickness according to one embodiment of the method disclosed herein.

FIG. 3 is a graph showing the results of the measurement of voltage-current characteristics in a bottom gate or top gate organic field-effect transistor (OFET) device obtained using a P3HT-b-PMMA copolymer with a thickness of 60 nm according to one embodiment of the method disclosed herein.

FIG. 4 is I-V output curve of the bottom gate OFET showing the results of the measurement of voltage-current characteristics in a bottom gate organic field-effect transistor (OFET) device obtained using a P3HT-b-PMMA copolymer with a thickness of 60 nm according to one embodiment of the method disclosed herein.

### DETAILED DESCRIPTION

Exemplary embodiments now will be described more fully hereinafter with reference to the accompanying drawings, in which exemplary embodiments are shown. This disclosure may, however, be embodied in many different forms and should not be construed as limited to the exemplary embodiments set forth therein. Rather, these exemplary embodiments are provided so that this disclosure will be thorough and complete, and will fully convey the scope of this disclosure to those skilled in the art. In the description, details of well-known features and techniques may be omitted to avoid unnecessarily obscuring the presented embodiments.

The terminology used herein is for the purpose of describing particular embodiments only and is not intended to be limiting of this disclosure. As used herein, the singular forms “a”, “an” and “the” are intended to include the plural forms as well, unless the context clearly indicates otherwise. Furthermore, the use of the terms a, an, etc. does not denote a limitation of quantity, but rather denotes the presence of at least one of the referenced item. It will be further understood that the terms “comprises” and/or “comprising”, or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Unless otherwise defined, all terms (including technical and scientific terms) used herein have the same meaning as commonly understood by one of ordinary skill in the art. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

In the drawings, like reference numerals in the drawings denote like elements. The shape, size and regions, and the like, of the drawing may be exaggerated for clarity.

According to one embodiment of the method disclosed herein, a solvent is selected under the consideration of various factors, such as a block copolymer having a non-conjugated polymer introduced to a poly(3-hexylthiophene) (P3HT) polymer, volatility, affinity to each polymer block and solubility, in order to improve the quality of an organic electronic device to which poly(3-hexylthiophene) is applied. In case of coating a polymer composition containing the block copolymer and the solvent onto a substrate, it is possible to control a self-assembled structure of a poly(3-hexylthiophene)-based block copolymer through a microphase separation phenomenon of the block copolymer in the resultant film and crystal induction phenomenon in a solution.

According to one embodiment of the method disclosed herein, it is possible to control the alignment of poly(3-hexylthiophene) crystal domains through the control of a self-assembled structure of a poly(3-hexylthiophene)-based block copolymer merely by carrying out a simple solution process using a selected solvent, and thus to produce self-assembled polymer structures suitable for high-quality organic electronic devices. As a result, it is possible to obtain polymer structures by a simplified process with high productivity at low cost.

In one embodiment, the non-conjugated polymer of the block copolymer includes amorphous polymethyl methacrylate (PMMA), but is not limited thereto. Accordingly, it is possible to control the alignment of poly(3-hexylthiophene) crystal domains by controlling the self-assembled structure of a P3HT-b-PMMA block copolymer represented by Chemical Formula I and particularly having amorphous PMMA introduced to poly(3-hexylthiophene):

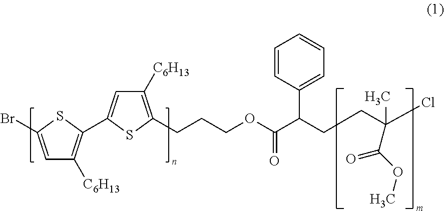

In another embodiment, the polymer composition may be coated onto a substrate through a solution process to form a film including a self-assembled polymer structure.

There is no particular limitation in the solution process, as long as it may be used for coating a composition containing a π-conjugated poly(3-hexylthiophene)-based block copolymer and a solvent. For example, the solution process may include at least one selected from the group consisting of drop-casting, spin-casting, ink-jet and printing processes, followed by post-treatment of the resultant film. More particularly, the solution process may be a drop-casting process.

In one embodiment, the solvent may be one in which both the π-conjugated poly(3-hexylthiophene) and the non-conjugated polymer are soluble. There is no particular limitation in the solvent, as long as it may be used for generating a microphase separation phenomenon of the poly(3-hexylthiophene)-based block copolymer and a crystal induction phenomenon in a solution in order to control the alignment of poly(3-hexylthiophene) crystal domains. More particularly, the solvent may be at least one selected from the group consisting of chloroform, tetrahydrofuran, chlorobenzene-like solvents and bromobenzene-like solvents. Specifically, when using chloroform as a solvent, it is possible to reduce the rigidity of a π-conjugated backbone by strong affinity between chloroform and poly(3-hexylthiophene), thereby controlling a microphase separated self-assembled structure.

There has been a report about casting of a film including a poly(3-hexylthiophene)-based block copolymer from toluene. However, such casting does not show the characteristics of a block copolymer depending on the chemical composition and molecular weight. This is because the copolymer having such strong π-π bonds prefers forming aggregates while they are converted into long nanofibrils on a solid substrate, in the presence of nonpolar toluene (boiling point=110.6° C., dipole moment (μ)=0.36 D) as a solvent. However, the method disclosed herein uses a solvent with affinity to blocks, thereby inducing a microphase separated structure during the film casting.

Herein, the coating may be performed to a thickness of 10-100 nm, specifically 20-80 nm. The critical coating thickness may also be controlled depending on the selection of organic solvent and the concentration of composition in such a manner that the poly(3-hexylthiophene) polymer domains are aligned from perpendicular to a substrate (a face-on alignment) to parallel with a substrate (an edge-on alignment) in the self-assembled polymer structure.

In addition, it is possible to control the three-dimensional structure of a block copolymer in the solution selectively using the affinity of poly(3-hexylthiophene) and polymethyl methacrylate to the solvent. Herein, the affinity of poly(3-hexylthiophene) and polymethyl methacrylate may be controlled by varying the molecular weight of each block.

Therefore, the poly(3-hexylthiophene) chain may have a number average molecular weight of 5-15 kDa. When the poly(3-hexylthiophene) chain has a molecular weight less than 5 kDa, a highly crystalline polymer structure is formed but clear inter-crystal boundaries are formed, resulting in a significant drop in inter-crystal hole transport. As a result, the resultant device may have lower quality than a device including poly(3-hexylthiophene) having a molecular weight of 5 kDa or higher and a low crystalline network structure. In contrast, when the poly(3-hexylthiophene) chain has a molecular weight greater than 15 kDa, it shows decreased solubility and requires a long time for crystallization.

Further, the poly(3-hexylthiophene) chain may be controlled to have a polydispersity (weight average molecular weight/number average molecular weight) of 1.05-1.17. When the poly(3-hexylthiophene) has an excessively broad molecular weight distribution, it is difficult to control the crystallization behavior and the microphase separated structure. Moreover, a rapid drop in solubility caused by an increase in molecular weight results in degradation of crystalline structure and alignment.

The substrate may be at least one selected from the group consisting of silicon, silicon oxide and a mixture of silicon with silicon oxide, or at least one polymer substrate selected from the group consisting of polyethylene terephthalate and polyethylene naphthalate. Optionally, the substrate may be coated with a self-assembled monolayer or crosslinkable polymer so as to control the surface energy to a water contact angle less than 60°.

The self-assembled monolayer may include gamma-aminopropyltriethoxysilane or alkoxysilane. The crosslinkable polymer may include UV-curable polyvinyl pyridine or polyhydroxystyrene. The self-assembled monolayer or crosslinkable polymer may be coated onto a substrate to control the surface energy of the substrate, thereby providing a controlled self-assembled structure having desired molecular alignment.

In another aspect, there is provided a self-assembled polymer structure including a π-conjugated poly(3-hexylthiophene)-based block copolymer and having a self-assembled structure controlled by coating a polymer composition, containing a block copolymer having a non-conjugated polymer introduced to the poly(3-hexylthiophene) polymer and a solvent, onto a substrate.

In one embodiment, the polymer structure may include poly(3-hexylthiophene) crystal domains having cylindrical structures with perpendicular direction to the substrate (face-on alignment to the substrate) through the controlled self-assembled structure. It is observed that when coating a polymer composition, including a block copolymer containing a π-conjugated poly(3-hexylthiophene) polymer and a non-conjugated polymer introduced thereto, and chlorobenzene as a solvent, onto a hydrophilic substrate (water contact angle<60°), controlling the thickness of the polymer coated on the substrate to 20 nm-30 nm during the evaporation of the solvent allows formation of a self-assembled polymer structure including poly(3-hexylthiophene) crystal domains having cylindrical structures with complete alignment with perpendicular direction to the substrate.

In another embodiment, the polymer structure may include poly(3-hexylthiophene) crystal domains having lower cylindrical structures oriented with perpendicular direction to the substrate, and upper nanofibrillar lamella structures oriented with parallel direction to the substrate connecting the lower cylindrical structures with each other, through the controlled self-assembled structure. It is observed that when coating a polymer composition, including a block copolymer containing a π-conjugated poly(3-hexylthiophene) polymer and a non-conjugated polymer introduced thereto, and a solvent, onto a substrate, controlling the thickness of the polymer composition coated on the substrate to 30 nm or higher allows the upper lamella structures to connect the lower cylindrical structures with each other. In addition, controlling the thickness to 50 nm or higher, upper lamella structures are formed over the whole film surface.

In still another embodiment, the polymer structure may include poly(3-hexylthiophene) crystal domains having structures of laminated nanofibrillar lamella which is oriented with parallel direction to the substrate through the controlled self-assembled structure. It is observed that when coating a polymer composition, including a block copolymer containing a π-conjugated poly(3-hexylthiophene) polymer and a non-conjugated polymer introduced thereto, and a solvent, onto a substrate, controlling the thickness of the polymer composition coated on the substrate to 50 nm or higher, specifically to 80 nm or higher, allows the smectic nanofibrillar lamella to be formed uniformly over the whole film. Particularly, the film thickness that allows face-on/edge-on transition of the domains in the self-assembled polymer structure may be controlled up to 150 nm or higher by controlling the solvent evaporation rate and the surface energy of the substrate.

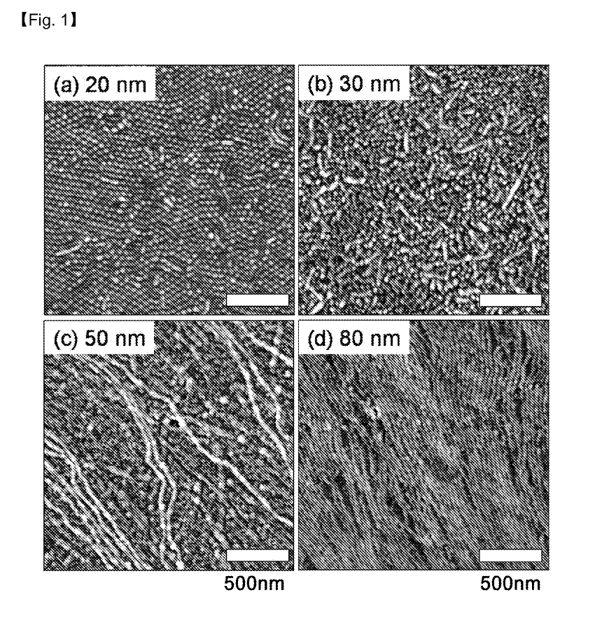

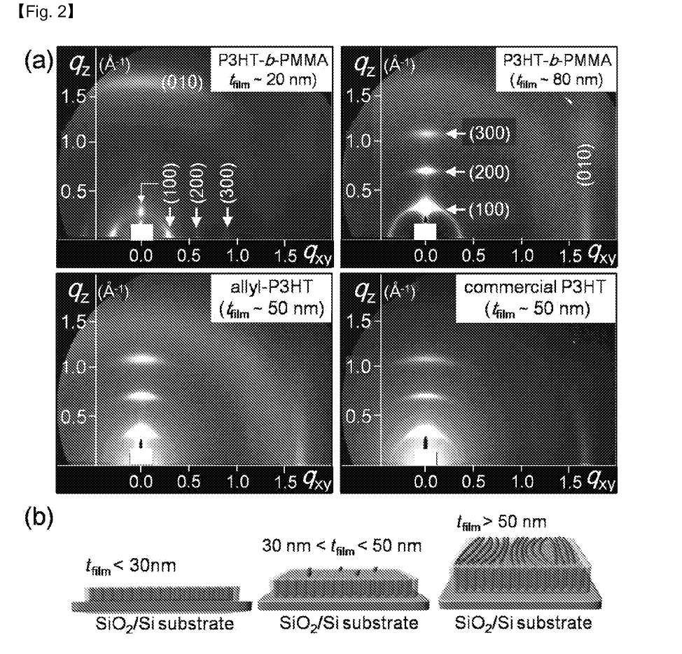

Particularly, FIG. 1 is a photographic view illustrating the atomic force microscope (ATM) images (a-d) of a self-assembled polymer structure having different alignments of poly(3-hexylthiophene) domains depending on the coating thickness on a substrate, when using a polymer composition, containing poly(3-hexylthiophene)-polymethyl methacrylate diblock copolymer and chlorobenzene as an organic solvent, according to one embodiment of the method disclosed herein. FIG. 2 (b) is a schematic view illustrating different microphase separation behaviors depending on the coating thickness on the substrate.

Referring to FIG. 1 and FIG. 2, the self-assembled polymer structure has a self-assembled morphology controlled according to the coating thickness. Particularly, the structure and alignment of poly(3-hexylthiophene) conductive domains may be controlled selectively. In other words, it is observed that poly(3-hexylthiophene) domains may have cylindrical structures oriented with perpendicular direction to a substrate; lower cylindrical structures oriented with perpendicular direction to the substrate and upper lamella structures oriented with parallel direction to the substrate connecting the lower cylindrical structures; or conductive laminated nanofibrillar lamella structures which are oriented with parallel direction to the substrate and having a periodic structure in which molecular axes are positioned regularly toward one direction.

In still another aspect, there is provided an organic electronic device including the self-assembled polymer structure. The organic electronic device disclosed herein has a self-assembled structure controlled through a microphase separation phenomenon and a crystal induction phenomenon in a solution, and thus realizes excellent quality through the self-assembled polymer structure including poly(3-hexylthiophene) crystal domains aligned in a controlled manner.

The organic electronic device may be an organic field-effect transistor (OFET) or a photovoltaic device, such as a photovoltaic cell. The OFET may include a self-assembled polymer structure controlled in such a manner that it has conductive poly(3-hexylthiophene) crystal domains with edge-on alignment to a substrate, and may be used as an organic semiconductor material forming an active layer in an OFET device, but is not limited thereto.

In a variant, the photovoltaic device may include a self-assembled polymer structure controlled in such a manner that it has conductive poly(3-hexylthiophene) crystal domains having cylindrical structures oriented with perpendicular direction to a substrate, and may be used as a key material, such as a charge generating or transport layer, in a photovoltaic device, but is not limited thereto.

In the organic electronic device based on poly(3-hexylthiophene), holes applied to the poly(3-hexylthiophene) crystal domains arrive at a final electrode along the π-orbital overlapping direction to generate current flow. Therefore, it is ideal that the crystal structure and alignment of poly(3-hexylthiophene) crystal domains participating in charge transport conform to the direction of the electrode in the electronic device.

In this manner, when the self-assembled structure of the poly(3-hexylthiophene)-based block copolymer is controlled so that the poly(3-hexylthiophene) crystal domains have structures oriented with parallel direction to a substrate, it is possible to realize high quality in a top gate type organic field effect transistor. When the poly(3-hexylthiophene) crystal domains are formed with face-on alignment to the substrate, it is possible to transport holes easily to negative electrodes of organic photovoltaics (OPV), and thus to realize excellent quality in organic photovoltaics. Therefore, the self-assembled polymer structure including the alignment-controlled poly(3-hexylthiophene) crystal domains may be useful for designing and developing various high-quality devices.

Most current studies about organic photovoltaics have succeeded merely in controlling the nano-network structure and crystallinity of poly(3-hexylthiophene) domains, and the maximum efficiency obtained from such organic photovoltaics still remains at about 6.5%. This is because the poly(3-hexylthiophene) used in organic photovoltaics is formed to have a structure with parallel direction to a substrate through general post-treatment processes.

However, it is now shown that a self-assembled polymer structure including poly(3-hexylthiophene) crystal domains oriented with perpendicular direction to the substrate may be obtained by controlling the thickness of a polymer composition, containing a block copolymer and a solvent, coated on the substrate. It is possible to improve the efficiency of organic photovoltaics significantly by applying the self-assembled polymer structure. Particularly, the method disclosed herein controls the molecular alignment of a conductive block copolymer through a single process using a desired solvent instead of using a large number of processes. As a result, the method disclosed herein allows reduction of a hole transport distance to a lower electrode using self-assembled p-type face-on domains having a diameter of 30 nm or less. There has been no suggestion or description about such a result according to the related art.

The examples (and experiments) will now be described. The following examples (and experiments) are for illustrative purposes only and not intended to limit the scope of this disclosure.

### Example 1

### Preparation of Self-Assembled Polymer Structure Having Controlled Domain Alignment

Chlorobenzene (Tb=131° C., μ=1.60 D) is used as a solvent, since it causes a microphase separated morphology in P3HT-b-PMMA and has strong affinity to both blocks. A well-aligned P3HT phase is induced on a SiO₂/Si substrate. The results are shown in FIG. 1. In the initially formed droplets on the substrate, the copolymer starts self-assembly by the PMMA segments surrounding the P3HT blocks. These P3HT crystal domains are grown in the face-on direction in cylindrical forms until they reach the critical thickness (t_{c}) on the substrate (FIGS. 1 (b) and (c)). When the finally formed film thickness exceeds t_{c} as the concentration of P3HT increases in the solution, long P3HT nanofibrils start to be formed over the face-on P3HT domains. As the thickness of the casting film increases (for example, film thickness (t_{film})>80 nm), the nanofibrils completely cover the air/film interface (FIG. 1 (d)).

Such a change in self-assembly characteristics of the block copolymer depending on the film thickness is also demonstrated through grazing-incidence X-ray diffractometry (GIXD) (FIG. 2 (a)). As can be seen in the two-dimensional GIXD pattern of a 20 nm-thickness film, most P3HT chains in the standing domains have face-on alignment to the substrate. It is observed that such face-on alignment competes with thermally stable edge-on alignment, as the film thickness (t_{film}) increases.

### Experimental Example 1

### Determination of Quality of Electronic Device

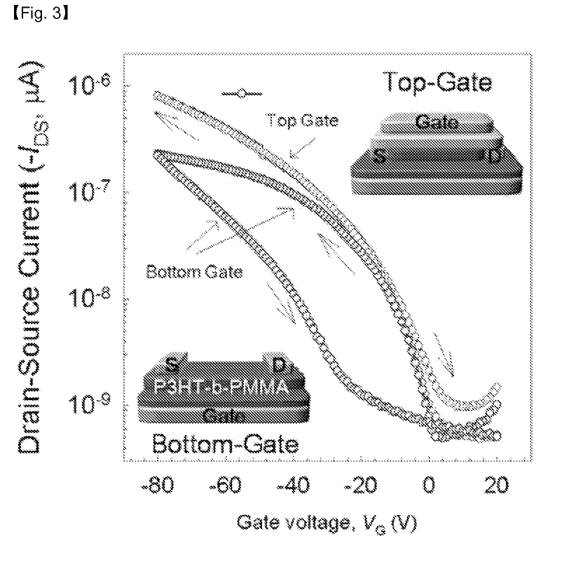

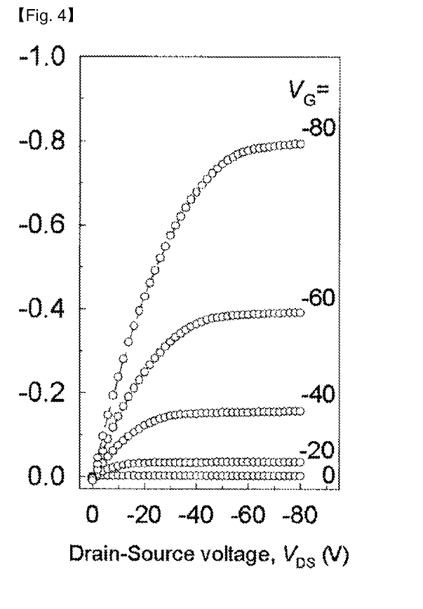

In the P3HT-b-PMMA cast film obtained from a solution in chlorobenzene (CB), conductive P3HT domains have face-on alignment to the substrate. To obtain high-quality OFET devices using such films, a top gate OFET device is fabricated and is compared with a general bottom gate OFET device. FIG. 3 is a graph showing the general current-voltage (I-V) characteristics in the bottom gate and top gate OFET devices including a P3HT-b-PMMA cast film with a thickness of 60 nm. FIG. 3 is the I_{DS}-V_{G} transfer curves of the top gate and bottom gate OFETs, and FIG. 4 is the I-V output curve of the bottom gate OFET. As can be seen from FIGS. 3 and 4, the bottom gate OFET device based on the P3HT-b-PMMA film shows a low charge mobility (μ_{FET}<0.0001 cm²/Vs) and high hysteresis due to the face-on alignment of P3HT domains unfavorable to charge transport on the interface with an insulation layer, SiO₂ (300 nm). Such properties are not improved significantly even after heat treatment. On the contrary, the top gate OFET device shows excellent charge mobility (μ_{FET}=0.015 cm²/Vs) due to the edge-on alignment of conductive P3HT domains to the upper insulation layer.

While the exemplary embodiments have been shown and described, it will be understood by those skilled in the art that various changes in form and details may be made thereto without departing from the spirit and scope of this disclosure as defined by the appended claims.

In addition, many modifications can be made to adapt a particular situation or material to the teachings of this disclosure without departing from the essential scope thereof. Therefore, it is intended that this disclosure not be limited to the particular exemplary embodiments disclosed as the best mode contemplated for carrying out this disclosure, but that this disclosure will include all embodiments falling within the scope of the appended claims.

What is claimed is:

1. A method for controlling a self-assembled structure of a poly(3-hexylthiophene)-based block copolymer, comprising:
preparing a polymer composition containing a block copolymer having a π-conjugated poly(3-hexylthiophene) polymer and a non-conjugated polymer introduced thereto, and a solvent; and
coating the polymer composition onto a substrate.

2. The method for controlling a self-assembled structure of a poly(3-hexylthiophene)-based block copolymer according to claim 1, wherein the non-conjugated polymer is amorphous polymethyl methacrylate (PMMA).

3. The method for controlling a self-assembled structure of a poly(3-hexylthiophene)-based block copolymer according to claim 1, wherein the polymer composition is coated onto the substrate via a solution process.

4. The method for controlling a self-assembled structure of a poly(3-hexylthiophene)-based block copolymer according to claim 3, wherein the solution process includes at least one process selected from the group consisting of drop-casting, spin-casting, ink-jet and printing processes.

5. The method for controlling a self-assembled structure of a poly(3-hexylthiophene)-based block copolymer according to claim 1, wherein the solvent is one capable of dissolving both the poly(3-hexylthiophene) and the non-conjugated polymer therein.

6. The method for controlling a self-assembled structure of a poly(3-hexylthiophene)-based block copolymer according to claim 5, wherein the solvent is at least one selected from the group consisting of chloroform, tetrahydrofuran, chlorobenzene-based solvents and bromobenzene-based solvents.

7. The method for controlling a self-assembled structure of a poly(3-hexylthiophene)-based block copolymer according to claim 1, wherein the polymer composition is coated to a thickness of 10-100 nm.

8. The method for controlling a self-assembled structure of a poly(3-hexylthiophene)-based block copolymer according to claim 1, wherein the poly(3-hexylthiophene) has a number average molecular weight of 5-15 kDa.

9. The method for controlling a self-assembled structure of a poly(3-hexylthiophene)-based block copolymer according to claim 1, wherein the poly(3-hexylthiophene) has a polydispersity (weight average molecular weight/number average molecular weight) of 1.05-1.17.

10. The method for controlling a self-assembled structure of a poly(3-hexylthiophene)-based block copolymer according to claim 1, wherein the polymer composition is coated onto a substrate having surface energy controlled by being coated with a self-assembled monolayer or crosslinkable polymer.

11. A self-assembled polymer structure comprising a π-conjugated poly(3-hexylthiophene)-based block copolymer, which has a self-assembled structure controlled by coating a polymer composition, containing a block copolymer having a non-conjugated polymer introduced to the poly(3-hexylthiophene) polymer and a solvent, onto a substrate.

12. The self-assembled polymer structure according to claim 11, wherein the polymer structure comprises poly(3-hexylthiophene) crystal domains having cylindrical structures oriented with perpendicular direction to the substrate.

13. The self-assembled polymer structure according to claim 12, wherein the polymer composition coated on the substrate has a thickness of 20-30 nm.

14. The self-assembled polymer structure according to claim 11, wherein the polymer structure comprises poly(3-hexylthiophene) crystal domains having lower cylindrical structures oriented with perpendicular direction to the substrate and upper nanofibrillar lamella structures oriented with parallel direction to the substrate connecting the lower cylindrical structures with each other.

15. The self-assembled polymer structure according to claim 14, wherein the polymer composition coated on the substrate has a thickness of 30-50 nm.

16. The self-assembled polymer structure according to claim 11, wherein the polymer structure comprises poly(3-hexylthiophene) crystal domains having structures of laminated nanofibrillar lamella which is oriented with parallel direction to the substrate.

17. The self-assembled polymer structure according to claim 16, wherein the polymer composition coated on the substrate has a thickness of 50-150 nm.

18. An organic electronic device comprising the self-assembled polymer structure as defined in claim 11.

19. The organic electronic device according to claim 18, which is an organic field-effect transistor (OFET).

20. The organic electronic device according to claim 18, which is a photovoltaic cell.
